(19) United States
(12) Patent Application Publication
(10) Pub. No.: US 2011/0186827 A1
(43) Pub. Date: Aug. 4, 2011

(54) Organic Light-emitting Materials and Devices

(75) Inventors: Torsten Buennagel, Cambridge (GB); Thomas Pounds, Cambridge (GB); Mary Mckierman, Cottenham (GB)

(73) Assignees: Cambridge Display Technology Limited, Cambridgeshire (GB); Sumation Company Limited, Chuo-ku, TOKYO (JP)

(21) Appl. No.: 13/056,107

(22) PCT Filed: Jul. 30, 2009
(86) PCT No.: PCT/GB2009/001869

§ 371 Date: Mar. 14, 2011

(30) Foreign Application Priority Data
Aug. 1, 2008 (GB) 0814158.2

(51) Int. Cl. H01L 51/54; H01L 51/56; C08G 75/06; C08G 85/00

(52) U.S. Cl. 257/40; 438/46; 528/380; 257/E51.027; 257/E51.018

(57) ABSTRACT

A light-emissive polymer comprising the following unit:

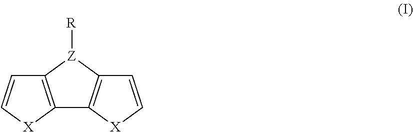

where X is one of S, O, P and N; Z is N or P; and R is an alkyl wherein one or more non-adjacent C atoms other that the C atom adjacent to Z may be replaced with O, S, N, C═O and —COO— or an optionally substituted aryl or heteroaryl group.

### FIELD OF THE INVENTION

The present invention is concerned with organic light-emitting materials and with organic light-emitting devices containing the same.

### BACKGROUND OF THE INVENTION

A typical organic light-emitting device (OLED) comprises a substrate, on which is supported an anode, a cathode and a light-emitting layer situated in between the anode and cathode and comprising at least one organic electroluminescent material. In operation, holes are injected into the device through the anode and electrons are injected into the device through the cathode. The holes and electrons combine in the light-emitting layer to form an exciton which then undergoes radioactive decay to emit light.

Other layers may be present in the OLED, for example a layer of hole injection material, such as poly(ethylene dioxythiophene)/polystyrene sulphonate (PEDOT/PSS), may be provided between the anode and the light-emitting layer to assist injection of holes from the anode to the light-emitting layer. Further, a hole transport layer may be provided between the anode and the light-emitting layer to assist transport of holes to the light-emitting layer.

Electroluminescent polymers such as conjugated polymers are an important class of materials that will be used in organic light emitting devices for the next generation of information technology based consumer products. The principle interest in the use of polymers, as opposed to inorganic semiconducting and organic dye materials, lies in the scope for low-cost device manufacturing, using solution-processing of film-forming materials. A further advantage of electroluminescent polymers is that they may be readily formed by Suzuki or Yamamoto polymerisation. This enables a high degree of control over the regioregularity of the resultant polymer.

Since the last decade much effort has been devoted to the improvement of the emission efficiency of organic light-emitting devices either by developing highly efficient materials or efficient device structures. In addition, much effort has been devoted to the improvement in lifetime of organic light-emitting devices, again by developing new materials or device structures. Further still, much effort has been devoted to the development of materials having specific colours of emission and charge transporting properties.

In relation to the above, it is known to incorporate various fused aromatic derivatives into light-emissive polymers as light-emissive units and/or charge transporting units. Some of these are discussed below.

The present applicant has developed various carbazole derivatives for use as blue emissive units or hole transporting units in light emissive polymers.

WO 2007/071957 discloses units according to the following formula for use as blue emissive units and/or hole transport units:

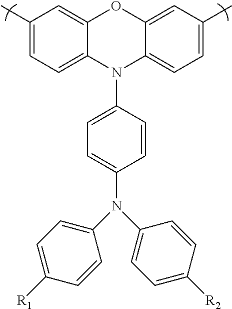

Here, R₁ and R₂ represent substituents such as alkyl. The repeat unit may be formed by polymerising a corresponding monomer comprising bromine leaving groups. The light emissive polymer may also comprise other charge transporting and/or light-emissive repeat units such as fluorene repeat units.

Chemistry Letters, vol. 36, No. 10, pp 1206-1207 (2007) discloses the use of dithienothiophene repeat units in a light-emissive polymer according to the following formulae:

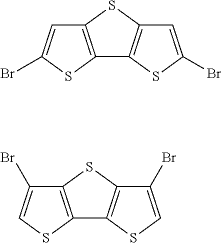

Light-emissive co-polymers comprising these repeat units in combination with fluorene repeat units are disclosed. It is disclosed that the polymers emit yellow-green light.

In light of the above, it is apparent that it is known to incorporate polycyclic heteroaromatic units such as carbazoles, biphenylamino derivatives and dithienothiophene into a light-emissive polymer in order to act as light-emissive units and/or charge transport units.

One problem with the aforementioned polycyclic heteroaromatic units is that they have a tendency to trap charge thus reducing charge carrier mobility in a polymer comprising these units.

It is an aim of embodiments of the present invention to provide new organic light-emitting materials, methods of manufacturing said materials using light-emissive and/or charge transporting units, and organic light-emitting devices containing said materials. It is also an aim of embodiments of the present invention to provide units which have a lower charge trapping ability than the previously described polycyclic heteroaromatic units thus providing light-emissive polymers which have improved charge carrier mobility.

### SUMMARY OF THE PRESENT INVENTION

In accordance with a first aspect of the present invention there is provided a polymer comprising the following unit:

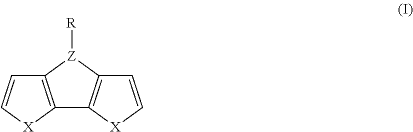

where X is one of S, O, P and N; Z is N or P; and R is an alkyl wherein one or more non-adjacent C atoms other that the C atom adjacent to Z may be replaced with O, S, N, C═O and —COO— or an optionally substituted aryl or heteroaryl group. The polymer is preferably a light emissive polymer.

In the case where R is aryl or heteroaryl, preferred optional substituents include alkyl groups wherein one or more non-adjacent C atoms may be replaced with O, S, N, C═O and —COO—.

The fused ring system of formula (I) may be substituted with one or more substituents. Preferred substituents include alkyl wherein one or more non-adjacent C atoms may be replaced with O, S, N, C═O and —COO—, optionally substituted aryl, optionally substituted heteroaryl, alkoxy, alkylthio, fluorine, cyano and aralykyl.

The present applicant has found that units according to Formula (I) have a lower charge trapping ability than the previously described polycyclic heteroaromatic units which results in the polymer having improved charge carrier mobility.

According to one preferred arrangement Z is N. X is preferably S. However, different ones of X and Z can be selected to tune the light-emissive polymer according to desired light-emissive and/or charge transporting properties, for example, to shift the emission colour of the polymer.

Similarly, the R group can be selected to tune the light-emissive polymer according to desired light-emissive and/or charge transporting properties. The R group can also be selected to change other physical properties of the polymer such as its solubility. Preferably R comprises an aryl group, for example a triarylamine group. The triarylamine group can function to aid hole transport. The triarylamine group may be substituted with alkyl or aryl groups, for example solubilising groups such as alkyl chains in order to increase the solubility of the polymer and thus aid solution processing. As such, the unit of formula (I) may have the following structure:

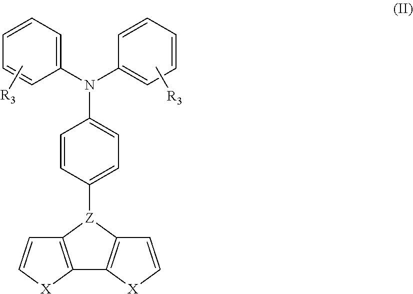

where X and Z are defined as previously indicated and R₃ is a substituent, for example an alkyl or aryl substituent, in particular a solubilising group such as an alkyl chain.

Depending on what other repeat units are provided in the polymer, the aforementioned repeat unit may be an emissive unit or a charge transporting repeat unit or both. The polymer may comprise an electron transporting unit such as a fluorene repeat unit. The polymer may also comprise a hole transporting repeat unit such as a triarylamine. Alternatively, the unit of the present invention may function as both an emissive unit and a hole transporting unit. Depending on which groups are selected for the X, Z and R groups, the unit may be a red or yellow emissive unit.

The unit may be bonded into the polymer via the heteroaromatic groups of Formula (I) or via the R group, most preferably via the heteroaromatic groups of formula (I). The unit may be incorporated into the polymer as repeat units in the main chain, in a side chain pendent to the polymer main chain, or an end capping group.

According to another aspect of the present invention there is provided a method of manufacturing a light-emissive polymer comprising incorporating monomer units including the structure of formula (I) into a polymer. The monomers may have polymerizable groups on the heteroaromatic groups of Formula (I) or in the R group, preferably on the heteroaromatic groups of formula (I). If the unit is to be incorporated into the polymer backbone as a repeat unit then two polymerizable groups Y are provided, for example, one on each heteroaromatic ring as shown below:

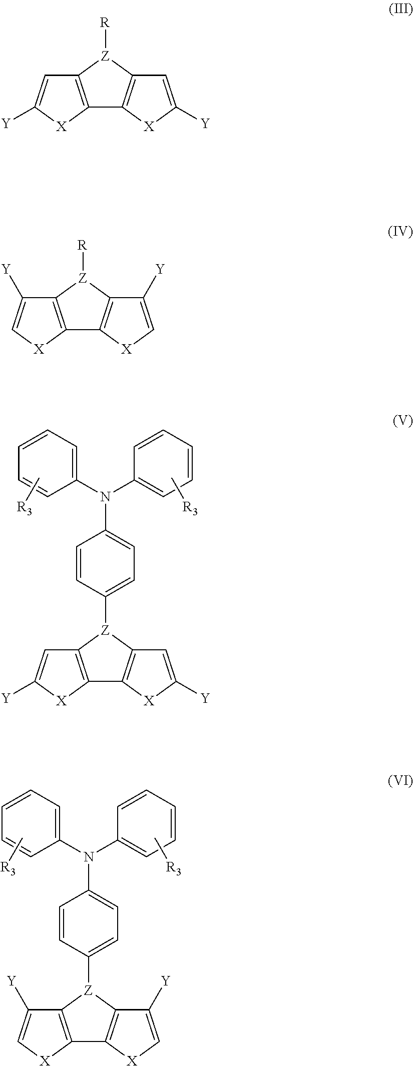

One particularly preferred monomer unit is shown below:

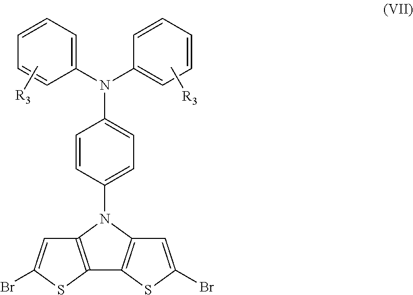

If the unit is to be incorporated into the polymer as an endcapping group then only one polymerizable group is required.

According to another aspect of the present invention the previously described monomer units are used to manufacture a light-emissive polymer. According to yet another aspect of the present invention the light-emissive polymer is used to manufacture an organic light emissive device comprising: an anode; a cathode; and a light-emissive layer disposed between the anode and the cathode, wherein the light emissive layer comprises a light-emissive polymer as previously described.

### BRIEF DESCRIPTION OF THE DRAWINGS

The present invention will now be described by way of example only with reference to the following drawing:

FIG. 1 shows an organic light emissive device in accordance with an embodiment of the present invention; and

### DETAILED DESCRIPTION OF EMBODIMENTS

An example of the present invention is described here in relation to the following monomer unit:

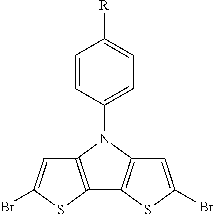

where R is an alkyl or aryl substituent.

The following synthetic route may be utilized to manufacture the monomer:

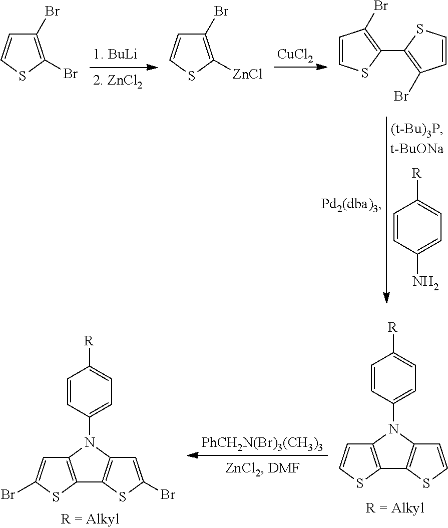

The following references give details of the various steps in the synthetic route:

Steps 1&2: S. M. H. Kabir et. al. Heterocycles, 2000, 671.

Step 3: K. Nozaki et. al. Angew. Chem. Int. Ed. 2003, 2051.

Step 4: similar procedure to T. W. Bünnagel et. al. Macromolecules, 2006, 8870.

An example of the aforementioned monomer is given below:

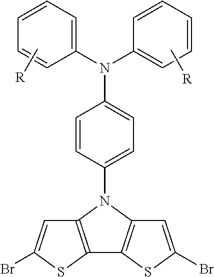

where R is an alkyl or aryl substituent, for example a solubilising group such as an alkyl chain.

The following synthetic route may be utilized to manufacture this monomer:

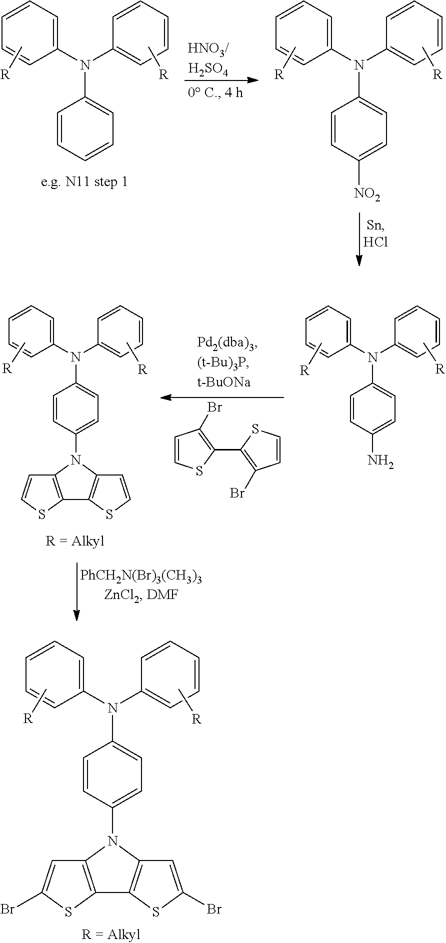

An alternative route to produce the intermediate nitro compound is given below:

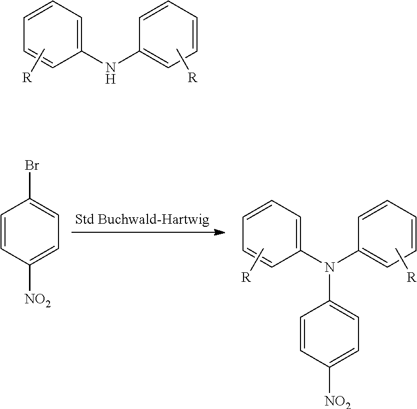

Other features of embodiments of the present invention are described below.

### General Device Architecture

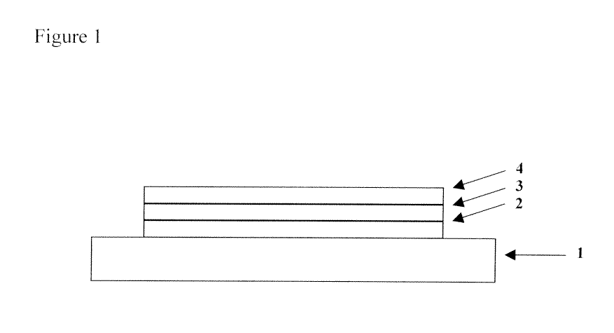

With reference to FIG. 1, the architecture of an electroluminescent device according to the invention comprises a transparent glass or plastic substrate 1, an anode 2 and a cathode 4. An electroluminescent layer 3 is provided between anode 2 and cathode 4.

In a practical device, at least one of the electrodes is semi-transparent in order that light may be absorbed (in the case of a photoresponsive device) or emitted (in the case of an OLED). Where the anode is transparent, it typically comprises indium tin oxide.

### Charge Transport Layers

Further layers may be located between anode 2 and cathode 3, such as charge transporting, charge injecting or charge blocking layers.

In particular, it is desirable to provide a conductive hole injection layer, which may be formed from a conductive organic or inorganic material provided between the anode 2 and the electroluminescent layer 3 to assist hole injection from the anode into the layer or layers of semiconducting polymer. Examples of doped organic hole injection materials include doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and poly(thienothiophene). Examples of conductive inorganic materials include transition metal oxides such as VOx MoOx and RuOx as disclosed in Journal of Physics D: Applied Physics (1996), 29(11), 2750-2753.

If present, a hole transporting layer located between anode 2 and electroluminescent layer 3 preferably has a HOMO level of less than or equal to 5.5 eV, more preferably around 4.8-5.5 eV. HOMO levels may be measured by cyclic voltammetry, for example.

If present, an electron transporting layer located between electroluminescent layer 3 and cathode 4 preferably has a LUMO level of around 3-3.5 eV.

### Electroluminescent Layer

Electroluminescent layer 3 may consist of the electroluminescent material alone or may comprise the electroluminescent material in combination with one or more further materials. In particular, the electroluminescent material may be blended with hole and/or electron transporting materials as disclosed in, for example, WO 99/48160, or may comprise a luminescent dopant in a semiconducting host matrix. Alternatively, the electroluminescent material may be covalently bound to a charge transporting material and/or host material.

Electroluminescent layer 3 may be patterned or unpatterned. A device comprising an unpatterned layer may be used an illumination source, for example. A white light emitting device is particularly suitable for this purpose. A device comprising a patterned layer may be, for example, an active matrix display or a passive matrix display. In the case of an active matrix display, a patterned electroluminescent layer is typically used in combination with a patterned anode layer and an unpatterned cathode. In the case of a passive matrix display, the anode layer is formed of parallel stripes of anode material, and parallel stripes of electroluminescent material and cathode material arranged perpendicular to the anode material wherein the stripes of electroluminescent material and cathode material are typically separated by stripes of insulating material (“cathode separators”) formed by photolithography.

Suitable materials for use in layer 3 include small molecule, polymeric and dendrimeric materials, and compositions thereof.

### Cathode

Cathode 4 is selected from materials that have a workfunction allowing injection of electrons into the electroluminescent layer. Other factors influence the selection of the cathode such as the possibility of adverse interactions between the cathode and the electroluminescent material. The cathode may consist of a single material such as a layer of aluminium. Alternatively, it may comprise a plurality of metals, for example a bilayer of a low workfunction material and a high workfunction material such as calcium and aluminium as disclosed in WO 98/10621; elemental barium as disclosed in WO 98/57381, Appl. Phys. Lett. 2002, 81(4), 634 and WO 02/84759; or a thin layer of metal compound, in particular an oxide or fluoride of an alkali or alkali earth metal, to assist electron injection, for example lithium fluoride as disclosed in WO 00/48258; barium fluoride as disclosed in Appl. Phys. Lett. 2001, 79(5), 2001; and barium oxide. In order to provide efficient injection of electrons into the device, the cathode preferably has a workfunction of less than 3.5 eV, more preferably less than 3.2 eV, most preferably less than 3 eV. Work functions of metals can be found in, for example, Michaelson, J. Appl. Phys. 48(11), 4729, 1977.

The cathode may be opaque or transparent. Transparent cathodes are particularly advantageous for active matrix devices because emission through a transparent anode in such devices is at least partially blocked by drive circuitry located underneath the emissive pixels. A transparent cathode will comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

### Encapsulation

Optical devices tend to be sensitive to moisture and oxygen. Accordingly, the substrate preferably has good barrier properties for prevention of ingress of moisture and oxygen into the device. The substrate is commonly glass, however alternative substrates may be used, in particular where flexibility of the device is desirable. For example, the substrate may comprise a plastic as in U.S. Pat. No. 6,268,695 which discloses a substrate of alternating plastic and barrier layers or a laminate of thin glass and plastic as disclosed in EP 0949850.

The device is preferably encapsulated with an encapsulant (not shown) to preventingress of moisture and oxygen. Suitable encapsulants include a sheet of glass, films having suitable barrier properties such as alternating stacks of polymer and dielectric as disclosed in, for example, WO 01/81649 or an airtight container as disclosed in, for example, WO 01/19142. A getter material for absorption of any atmospheric moisture and/or oxygen that may permeate through the substrate or encapsulant may be disposed between the substrate and the encapsulant.

### Other

The embodiment of FIG. 1 illustrates a device wherein the device is formed by firstly forming an anode on a substrate followed by deposition of an electroluminescent layer and a cathode, however it will be appreciated that the device of the invention could also be formed by firstly forming a cathode on a substrate followed by deposition of an electroluminescent layer and an anode.

Conjugated Polymers (Fluorescent and/or Charge Transporting)

Suitable electroluminescent and/or charge transporting polymers include poly(arylene vinylenes) such as poly(p-phenylene vinylenes) and polyarylenes.

Polymers preferably comprise a first repeat unit selected from arylene repeat units as disclosed in, for example, Adv. Mater. 2000 12(23) 1737-1750 and references therein. Examplary first repeat units include: 1,4-phenylene repeat units as disclosed in J. Appl. Phys. 1996, 79, 934; fluorene repeat units as disclosed in EP 0842208; indenofluorene repeat units as disclosed in, for example, Macromolecules 2000, 33(6), 2016-2020; and spirofluorene repeat units as disclosed in, for example EP 0707020. Each of these repeat units is optionally substituted. Examples of substituents include solubilising groups such as C₁₋₂₀ alkyl or alkoxy; electron withdrawing groups such as fluorine, nitro or cyano; and substituents for increasing glass transition temperature (Tg) of the polymer.

Particularly preferred polymers comprise optionally substituted, 2,7-linked fluorenes, most preferably repeat units of formula:

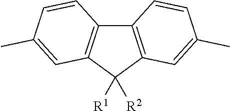

wherein R¹ and R² are independently selected from hydrogen or optionally substituted alkyl, alkoxy, aryl, arylalkyl, heteroaryl and heteroarylalkyl. More preferably, at least one of R¹ and R² comprises an optionally substituted C₄-C₂₀ alkyl or aryl group.

Polymers may provide one or more of the functions of hole transport, electron transport and emission depending on which layer of the device it is used in and the nature of co-repeat units.

In particular:

a homopolymer of fluorene repeat units, such as a homopolymer of 9,9-dialkylfluoren-2,7-diyl, may be utilised to provide electron transport.

a copolymer comprising triarylamine repeat unit, in particular a repeat unit 1:

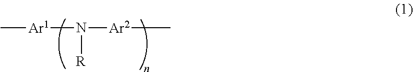

wherein Ar¹ and Ar² are optionally substituted aryl or heteroaryl groups, n is greater than or equal to 1, preferably 1 or 2, and R is H or a substituent, preferably a substituent. R is preferably alkyl or aryl or heteroaryl, most preferably aryl or heteroaryl. Any of the aryl or heteroaryl groups in the unit of formula 1 may be substituted. Preferred substituents include alkyl and alkoxy groups. Any of the aryl or heteroaryl groups in the repeat unit may be linked by a direct bond or a divalent linking atom or group. Preferred divalent linking atoms and groups include O, S; substituted N; and substituted C.

Particularly preferred units satisfying Formula 1 include units of Formulae 2-4:

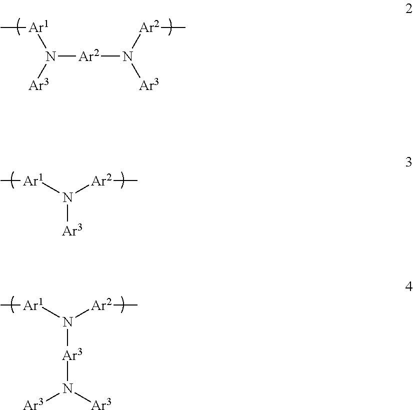

wherein Ar¹ and Ar² are as defined above; and Ar³ is optionally substituted aryl or heteroaryl. Where present, preferred substituents for Ar³ include alkyl and alkoxy groups.

Particularly preferred hole transporting polymers of this type are copolymers of the fluorene repeat units and the triarylamine repeat units.

a copolymer comprising one of the aforementioned repeat units and heteroarylene repeat unit may be utilised for charge transport or emission. Preferred heteroarylene repeat units are selected from formulae 7-21:

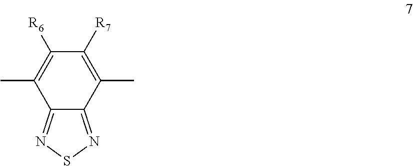

wherein R₆ and R₇ are the same or different and are each independently hydrogen or a substituent group, preferably alkyl, aryl, perfluoroalkyl, thioalkyl, cyano, alkoxy, heteroaryl, alkylaryl or arylalkyl. For ease of manufacture, R₆ and R_{7 are preferably the same. More preferably, they are the same and are each a phenyl group.}

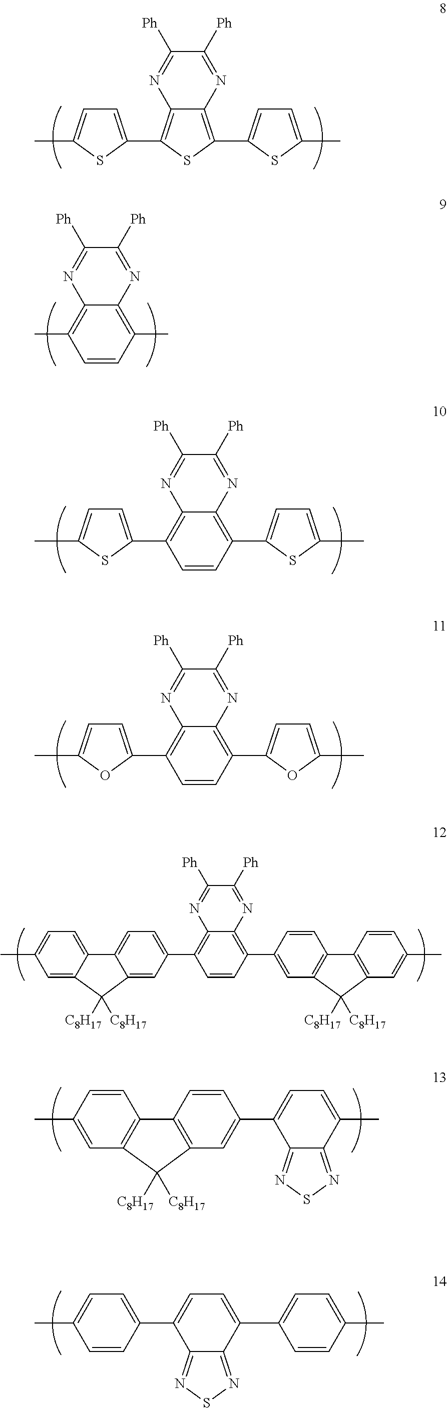

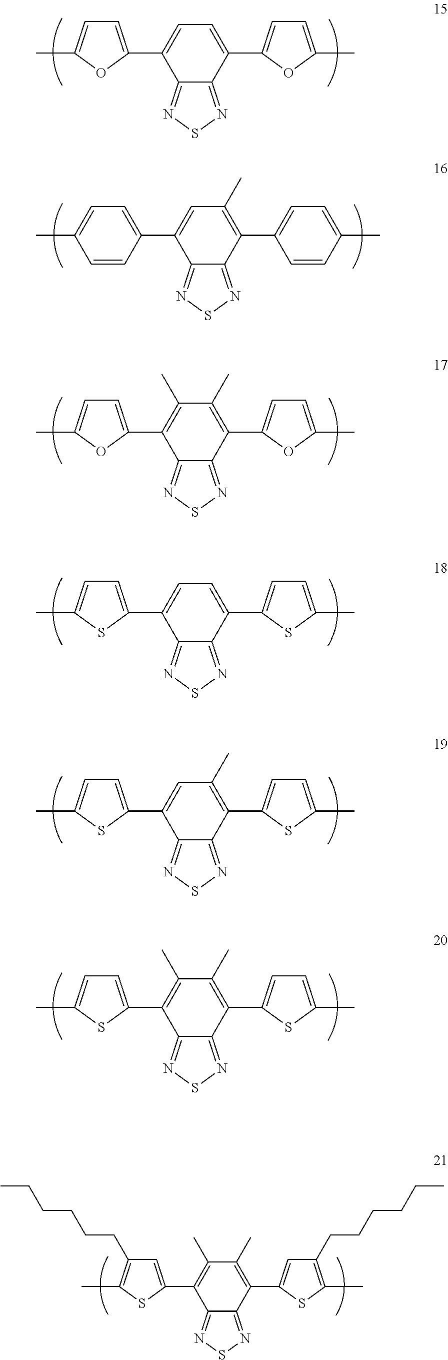

Electroluminescent copolymers may comprise an electroluminescent region and at least one of a hole transporting region and an electron transporting region as disclosed in, for example, WO 00/55927 and U.S. Pat. No. 6,353,083. If only one of a hole transporting region and electron transporting region is provided then the electroluminescent region may also provide the other of hole transport and electron transport functionality. Alternatively, an electroluminescent polymer may be blended with a hole transporting material and/or an electron transporting material. Polymers comprising one or more of a hole transporting repeat unit, electron transporting repeat unit and emissive repeat unit may provide said units in a polymer main-chain or polymer side-chain.

The different regions within such a polymer may be provided along the polymer backbone, as per U.S. Pat. No. 6,353,083, or as groups pendant from the polymer backbone as per WO 01/62869.

### Polymerisation Methods

Preferred methods for preparation of these polymers are Suzuki polymerisation as described in, for example, WO 00/53656 and Yamamoto polymerisation as described in, for example, T. Yamamoto, “Electrically Conducting And Thermally Stable π—Conjugated Poly(arylene)s Prepared by Organometallic Processes”, Progress in Polymer Science 1993, 17, 1153-1205. These polymerisation techniques both operate via a “metal insertion” wherein the metal atom of a metal complex catalyst is inserted between an aryl group and a leaving group of a monomer. In the case of Yamamoto polymerisation, a nickel complex catalyst is used; in the case of Suzuki polymerisation, a palladium complex catalyst is used.

For example, in the synthesis of a linear polymer by Yamamoto polymerisation, a monomer having two reactive halogen groups is used. Similarly, according to the method of Suzuki polymerisation, at least one reactive group is a boron derivative group such as a boronic acid or boronic ester and the other reactive group is a halogen. Preferred halogens are chlorine, bromine and iodine, most preferably bromine.

It will therefore be appreciated that repeat units and end groups comprising aryl groups as illustrated throughout this application may be derived from a monomer carrying a suitable leaving group.

Suzuki polymerisation may be used to prepare regioregular, block and random copolymers. In particular, homopolymers or random copolymers may be prepared when one reactive group is a halogen and the other reactive group is a boron derivative group. Alternatively, block or regioregular, in particular AB, copolymers may be prepared when both reactive groups of a first monomer are boron and both reactive groups of a second monomer are halogen.

As alternatives to halides, other leaving groups capable of participating in metal insertion include groups include tosylate, mesylate and triflate.

### Solution Processing

A single polymer or a plurality of polymers may be deposited from solution to form layer 5. Suitable solvents for polyarylenes, in particular polyfluorenes, include mono- or poly-alkylbenzenes such as toluene and xylene. Particularly preferred solution deposition techniques are spin-coating and inkjet printing.

Spin-coating is particularly suitable for devices wherein patterning of the electroluminescent material is unnecessary—for example for lighting applications or simple monochrome segmented displays.

Inkjet printing is particularly suitable for high information content displays, in particular full colour displays. Inkjet printing of OLEDs is described in, for example, EP 0880303.

Other solution deposition techniques include dip-coating, roll printing and screen printing.

If multiple layers of the device are formed by solution processing then the skilled person will be aware of techniques to prevent intermixing of adjacent layers, for example by crosslinking of one layer before deposition of a subsequent layer or selection of materials for adjacent layers such that the material from which the first of these layers is formed is not soluble in the solvent used to deposit the second layer.

### Emission Colours

By “red electroluminescent material” is meant an organic material that by electroluminescence emits radiation having a wavelength in the range of 600-750 nm, preferably 600-700 nm, more preferably 610-690 nm and most preferably having an emission peak around 650-660 nm.

By “green electroluminescent material” is meant an organic material that by electroluminescence emits radiation having a wavelength in the range of 510-580 nm, preferably 510-570 nm.

By “blue electroluminescent material” is meant an organic material that by electroluminescence emits radiation having a wavelength in the range of 400-500 nm, more preferably 430-500 nm.

### Hosts for Phosphorescent Emitters

Numerous hosts are described in the prior art including “small molecule” hosts such as 4,4′-bis(carbazol-9-yl)biphenyl), known as CBP, and (4,4′,4″-tris(carbazol-9-yl)triphenylamine), known as TCTA, disclosed in Ikai et al., Appl. Phys. Lett., 79 no. 2, 2001, 156; and triarylamines such as tris-4-(N-3-methylphenyl-N-phenyl)phenylamine, known as MTDATA. Polymers are also known as hosts, in particular homopolymers such as poly(vinyl carbazole) disclosed in, for example, Appl. Phys. Lett. 2000, 77(15), 2280; polyfluorenes in Synth. Met. 2001, 116, 379, Phys. Rev. B 2001, 63, 235206 and Appl. Phys. Lett. 2003, 82(7), 1006; poly[4-(N-4-vinylbenzyloxyethyl, N-methylamino)-N-(2,5-di-tert-butylphenylnapthalimide] in Adv. Mater. 1999, 11(4), 285; and poly(para-phenylenes) in J. Mater. Chem. 2003, 13, 50-55. Copolymers are also known as hosts.

### Metal Complexes (Phosphorescent and Fluorescent)

Preferred metal complexes comprise optionally substituted complexes of formula (22):

ML¹_{q}L²ᵣL³ₛ (22)

wherein M is a metal; each of L¹, L² and L³ is a coordinating group; q is an integer; r and s are each independently 0 or an integer; and the sum of (a. q)+(b. r)+(c.s) is equal to the number of coordination sites available on M, wherein a is the number of coordination sites on L¹, b is the number of coordination sites on L² and c is the number of coordination sites on L³.

Heavy elements M induce strong spin-orbit coupling to allow rapid intersystem crossing and emission from triplet or higher states (phosphorescence). Suitable heavy metals M include:

lanthanide metals such as cerium, samarium, europium, terbium, dysprosium, thulium, erbium and neodymium; and

d-block metals, in particular those in rows 2 and 3 i.e. elements 39 to 48 and 72 to 80, in particular ruthenium, rhodium, pallaidum, rhenium, osmium, iridium, platinum and gold.

Suitable coordinating groups for the f-block metals include oxygen or nitrogen donor systems such as carboxylic acids, 1,3-diketonates, hydroxy carboxylic acids, Schiff bases including acyl phenols and iminoacyl groups. As is known, luminescent lanthanide metal complexes require sensitizing group(s) which have the triplet excited energy level higher than the first excited state of the metal ion. Emission is from an f-f transition of the metal and so the emission colour is determined by the choice of the metal. The sharp emission is generally narrow, resulting in a pure colour emission useful for display applications.

The d-block metals are particularly suitable for emission from triplet excited states. These metals form organometallic complexes with carbon or nitrogen donors such as porphyrin or bidentate ligands of formula (23):

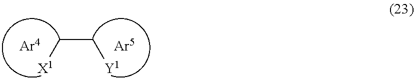

wherein Ar⁴ and Ar⁵ may be the same or different and are independently selected from optionally substituted aryl or heteroaryl; X¹ and Y¹ may be the same or different and are independently selected from carbon or nitrogen; and Ar⁴ and Ar⁵ may be fused together. Ligands wherein X¹ is carbon and Y¹ is nitrogen are particularly preferred.

Examples of bidentate ligands are illustrated below:

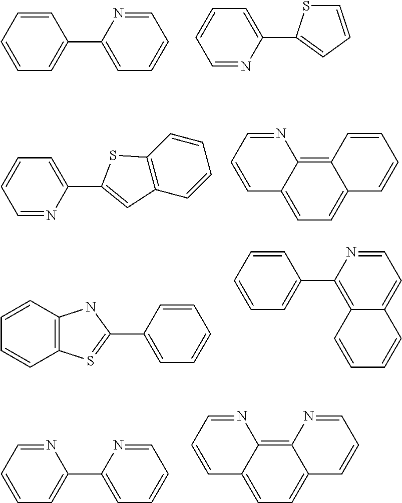

Each of Ar⁴ and Ar⁵ may carry one or more substituents. Two or more of these substituents may be linked to form a ring, for example an aromatic ring. Particularly preferred substituents include fluorine or trifluoromethyl which may be used to blue-shift the emission of the complex as disclosed in WO 02/45466, WO 02/44189, US 2002-117662 and US 2002-182441; alkyl or alkoxy groups as disclosed in JP 2002-324679; carbazole which may be used to assist hole transport to the complex when used as an emissive material as disclosed in WO 02/81448; bromine, chlorine or iodine which can serve to functionalise the ligand for attachment of further groups as disclosed in WO 02/68435 and EP 1245659; and dendrons which may be used to obtain or enhance solution processability of the metal complex as disclosed in WO 02/66552.

A light-emitting dendrimer typically comprises a light-emitting core bound to one or more dendrons, wherein each dendron comprises a branching point and two or more dendritic branches. Preferably, the dendron is at least partially conjugated, and at least one of the core and dendritic branches comprises an aryl or heteroaryl group. Other ligands suitable for use with d-block elements include diketonates, in particular acetylacetonate (acac); triarylphosphines and pyridine, each of which may be substituted.

Main group metal complexes show ligand based, or charge transfer emission. For these complexes, the emission colour is determined by the choice of ligand as well as the metal.

The host material and metal complex may be combined in the form of a physical blend. Alternatively, the metal complex may be chemically bound to the host material. In the case of a polymeric host, the metal complex may be chemically bound as a substituent attached to the polymer backbone, incorporated as a repeat unit in the polymer backbone or provided as an end-group of the polymer as disclosed in, for example, EP 1245659, WO 02/31896, WO 03/18653 and WO 03/22908.

A wide range of fluorescent low molecular weight metal complexes are known and have been demonstrated in organic light emitting devices [see, e.g., Macromol. Sym. 125 (1997) 1-48, U.S. Pat. No. 5,150,006, U.S. Pat. No. 6,083,634 and U.S. Pat. No. 5,432,014]. Suitable ligands for di or trivalent metals include: oxinoids, e.g. with oxygen-nitrogen or oxygen-oxygen donating atoms, generally a ring nitrogen atom with a substituent oxygen atom, or a substituent nitrogen atom or oxygen atom with a substituent oxygen atom such as 8-hydroxyquinolate and hydroxyquinoxalinol-10-hydroxybenzo (h) quinolinato (II), benzazoles (III), schiff bases, azoindoles, chromone derivatives, 3-hydroxyflavone, and carboxylic acids such as salicylato amino carboxylates and ester carboxylates. Optional substituents include halogen, alkyl, alkoxy, haloalkyl, cyano, amino, amido, sulfonyl, carbonyl, aryl or heteroaryl on the (hetero) aromatic rings which may modify the emission colour.

While this invention has been particularly shown and described with reference to preferred embodiments thereof, it will be understood by those skilled in the art that various changes in form and details may be made therein without departing from the scope of the invention as defined by the appended claims.

1. A polymer comprising the following unit: 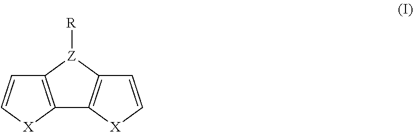
where X is one of S, O, P, and N;
Z is N or P; and,
R is an alkyl wherein one or more non-adjacent C atoms other that the C atom adjacent to Z each may be replaced with one of O, S, N, C═O, and —COO— or an optionally substituted aryl or heteroaryl group.

2. A polymer according to claim 1, wherein Z is N.

3. A polymer according to claim 1, wherein X is S.

4. A polymer according to claim 1, wherein R comprises an aryl group.

5. A polymer according to claim 4, wherein R comprises a triarylamine group.

6. A polymer according to claim 5, wherein the unit of formula (I) has the following structure: 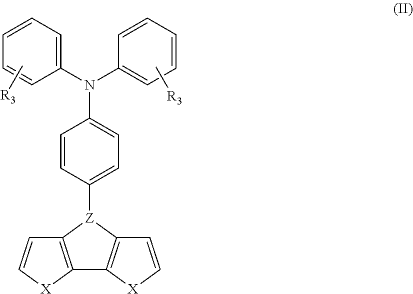
where R₃ is an alkyl or aryl substituent.

7. A polymer according to claim 6, wherein R is a solubilizing group.

8. A polymer according to claim 1, wherein the unit of Formula (I) is a light emissive unit.

9. A light-emissive polymer according to claim 8, wherein the unit of Formula (I) is a yellow-emitting unit.

10. A polymer according to claim 1, wherein the polymer is a co-polymer comprising one or more further charge transport and/or emissive units.

11. A polymer according to claim 10, wherein the one or more further charge transport and/or emissive units comprises an electron transporting unit.

12. A polymer according to claim 11, wherein the electron transporting unit is a fluorene repeat unit.

13. A polymer according to claim 10, wherein the one or more further charge transport and/or emissive units comprises a hole transporting repeat unit.

14. A polymer according to claim 13, wherein the hole transporting unit is a triarylamine repeat unit.

15. A polymer according to claim 1, wherein the unit of Formula (I) is bonded into the polymer via heteroaromatic rings of Formula (I) or via the R group.

16. A polymer according to claim 1, wherein the unit of Formula (I) is incorporated into the polymer as a repeat unit in the polymer's main chain, in a side chain pendent to the polymer's main chain, or as an end capping group.

17. A method for making a polymer claim 1 using Suzuki polymerization or Yamamoto polymerization whereby monomers are polymerized, each monomer having at least one reactive group.

18. A method according to claim 17, wherein the reactive groups are boron derivative groups a selected from the group consisting of boronic acids, boronic esters, halogen, tosylate, mesylate, and triflate.

19. An organic-light emitting device (OLED) comprising an anode, a cathode, and an electroluminescent layer comprising a polymer as defined in claim 1 between the anode and the cathode.

20. An OLED according to claim 19, comprising a conductive hole injection layer between the anode and the electroluminescent layer to assist hole injection from the anode into the electroluminescent layer.

21. A method of making an OLED as defined in claim 19 comprising depositing the polymer from solution by solution processing to form a layer of the OLED.

22. A method according to claim 21, wherein the solution processing technique is spin-coating or inkjet printing.

23. A light source comprising an OLED as defined in claim 19.

24. A light source according to claim 23, wherein the light source is a full color display.

25. A polymer according to claim 2, wherein X is S.

26. A polymer according to claim 6, wherein Z is N.

27. A polymer according to claim 6, wherein X is S.

28. A polymer according to claim 27, wherein X is S.

29. A method of making an OLED as defined in claim 20 comprising depositing the polymer from solution by solution processing to form a layer of the OLED.

30. A method according to claim 29, wherein the solution processing technique is spin-coating or inkjet printing.

31. A light source comprising an OLED as defined in claim 20.

32. A light source according to claim 31, wherein the light source is a full color display.
